(19) United States
(12) Patent Application Publication
(10) Pub. No.: US 2026/0082732 A1
(43) Pub. Date: Mar. 19, 2026

(54) LIGHT EMITTING ELEMENT, ELECTRONIC DEVICE, AND METHOD FOR MANUFACTURING LIGHT EMITTING ELEMENT

(71) Applicants: SOPHIA SCHOOL CORPORATION, TOKYO (JP); SEIKO EPSON CORPORATION, Tokyo (JP)

(72) Inventors: Shunsuke ISHIZAWA, MATSUMOTO SHI (JP); Katsumi KISHINO, AKIRUNO-SHI (JP); Rie TOGASHI, Tokyo (JP)

(73) Assignees: SOPHIA SCHOOL CORPORATION, TOKYO (JP); SEIKO EPSON CORPORATION, Tokyo (JP)

(21) Appl. No.: 19/326,739

(22) Filed: Sep. 12, 2025

(30) Foreign Application Priority Data
Sep. 13, 2024 (JP) 2024-159104

(51) Int. Cl. H10H 20/815; H10H 20/01; H10H 20/825

(52) U.S. Cl. CPC H10H 20/815; H10H 20/01335; H10H 20/825

(57) ABSTRACT

A light emitting element includes a first semiconductor layer having a first surface, a second semiconductor layer having conductivity different from that of the first semiconductor layer, a light emitting layer disposed between the first semiconductor layer and the second semiconductor layer, and a buffer layer disposed between the light emitting layer and the first semiconductor layer. The light emitting layer has a stacked body in which InGaN layers and GaN layers are alternately stacked, and has a second surface that is a facet plane. A composition ratio of indium (In) in the InGaN layer having a highest composition of In in the light emitting layer is 30% or more. The buffer layer has a third surface that is a facet plane. The composition ratio of In in the buffer layer is 20% or more.

The present application is based on, and claims priority from JP Application Serial Number 2024-159104, filed Sep. 13, 2024, the disclosure of which is hereby incorporated by reference herein in its entirety.

### BACKGROUND

### 1. Technical Field

The present disclosure relates to a light emitting element, an electronic device, and a method for manufacturing the light emitting element.

### 2. Related Art

In the related art, as a light emitting element including a plurality of nanostructures, a light emitting element including a semiconductor substrate, a plurality of columnar nanostructures disposed on the semiconductor substrate, and an active layer disposed on the plurality of nanostructures has been known. The columnar nanostructure called nanocolumn, nanopillar, nanowire, or the like. The semiconductor material of the nanostructure of the light emitting element is selected according to a wavelength band of color light to be emitted. For example, a nitride-based compound is used for a nanostructure of a light emitting element that emits color light having a green wavelength band.

For example, JP-A-2008-244360 discloses a semiconductor light emitting element including an active layer made of a nitride-based compound semiconductor, an upper optical confinement layer and a lower optical confinement layer made of a nitride-based compound semiconductor having a superlattice structure and sandwiching the active layer, an upper cladding layer disposed above the upper optical confinement layer, and a lower cladding layer disposed below the lower optical confinement layer.

JP-A-2008-244360 is an example of the related art.

In the semiconductor light emitting element disclosed in JP-A-2008-244360, the optical confinement layers formed of a superlattice of indium gallium nitride (InGaN) and gallium nitride (GaN) are disposed above and below the active layer. In general, when a composition ratio of indium (In) in InGaN stacked on GaN is increased, a wavelength band of color light emitted from the semiconductor light emitting element becomes longer, and specifically, green light, red light, or light in an infrared wavelength band can be emitted. Meanwhile, when the composition ratio of In in InGaN is increased, a difference in lattice constant between InGaN and GaN increases, threading dislocations occur, the crystal quality degrades, and light emission characteristics of the semiconductor light emitting element deteriorate.

In the semiconductor light emitting element disclosed in JP-A-2008-244360, phase separation of the active layer is prevented by disposing the optical confinement layer above and below the active layer, the crystal quality is improved, and the light emission characteristics are improved. However, in a case of emitting color light having a relatively long wavelength band such as green light or red light among color light having a visible wavelength band from the semiconductor light emitting element disclosed in JP-A-2008-244360, when a thickness of the optical confinement layer is to be secured, it is difficult to avoid the occurrence of crystal defects, and there is a high possibility that the crystal quality of the optical confinement layer degrades and the light emission characteristics of the semiconductor light emitting element deteriorate. Therefore, there is a demand for measures for achieving both a sufficient thickness for optical confinement and restriction of occurrence of crystal defects.

### SUMMARY

A light emitting element according to an aspect of the present disclosure includes a first semiconductor layer having a first surface, a second semiconductor layer having conductivity different from that of the first semiconductor layer, a light emitting layer disposed between the first semiconductor layer and the second semiconductor layer, and a buffer layer disposed between the light emitting layer and the first semiconductor layer. The light emitting layer has a stacked body in which indium gallium nitride (InGaN) layers and gallium nitride (GaN) layers are alternately stacked, and has a second surface that is a facet plane. A composition ratio of In in the InGaN layer having a highest composition of In in the light emitting layer is 30% or more. The buffer layer has a third surface that is a facet plane. The composition ratio of In in the buffer layer is 20% or more.

### BRIEF DESCRIPTION OF THE DRAWINGS

FIG. 1 is a schematic diagram of a projector according to an embodiment.

FIG. 2 is a plan view of a light emitting element of the projector in FIG. 1.

FIG. 3 is a cross-sectional view of the light emitting element in FIG. 2.

FIG. 4 is a cross-sectional view illustrating a method for manufacturing the light emitting element in FIG. 2.

FIG. 5 is a cross-sectional view illustrating a method for manufacturing the light emitting element in FIG. 2.

FIG. 6 is a cross-sectional view illustrating a method for manufacturing the light emitting element in FIG. 2.

FIG. 7 is a HAADF-STEM image of nanocolumns in a light emitting element of a first prototype example.

FIG. 8 is a HAADF-STEM image of nanocolumns in the light emitting element of the first prototype example, and is an enlarged view of a part in FIG. 7.

FIG. 9 is a graph of a composition ratio of nanocolumns in the light emitting element of the first prototype example.

FIG. 10 is a HAADF-STEM image of nanocolumns in a light emitting element of a second prototype example.

FIG. 11 is a graph of a composition ratio of nanocolumns in the light emitting element of the second prototype example.

### DESCRIPTION OF EMBODIMENTS

Hereinafter, a light emitting element, an electronic device, and a method for manufacturing the light emitting element according to embodiments will be described with reference to the drawings. In the following drawings, dimensions and scales of parts are appropriately different from those of an actual device. Unless otherwise stated in the following description, the scope of the present disclosure is not limited to the embodiments described below.

### Electronic Device

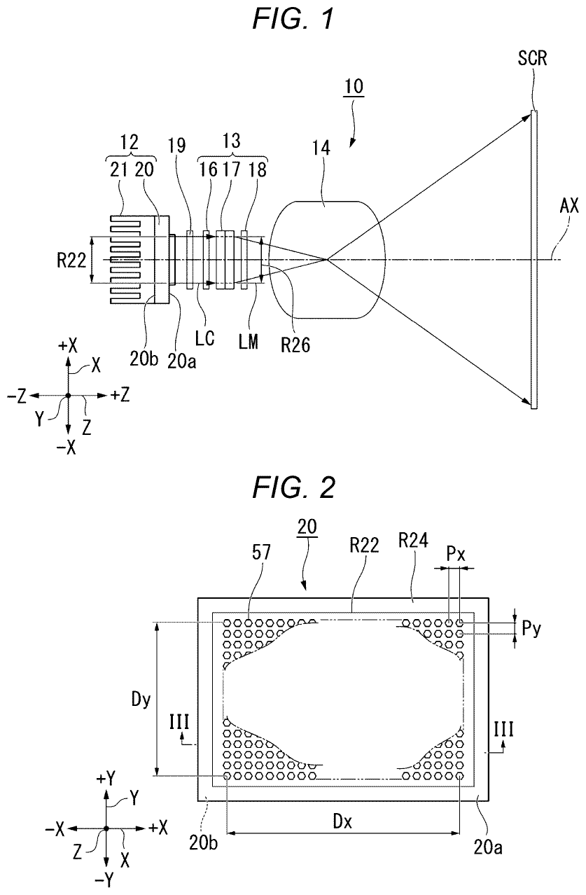

First, a projector 10 according to an embodiment of the present disclosure will be described. FIG. 1 is a schematic diagram of the projector 10. As illustrated in FIG. 1, the projector 10 is a projection-type image display device that includes a light emitting device 12, a diffusion plate 19, a light modulation device 13, and a projection optical system 14 and projects an image on a screen SCR. The projector 10 corresponds to an electronic device to be described later and an electronic device disclosed in the claims.

In the following description, an orthogonal coordinate system including an X axis, a Y axis, and a Z axis is used for describing each component. The Z axis is an axis parallel to an optical axis AX of light LC emitted from the light emitting device 12 described below, and corresponds to, for example, a thickness direction or an up-down direction. One side of the Z axis is described as a −Z side, and the other side of the Z axis is described as a +Z side. The X axis and the Y axis are orthogonal to the Z axis and are orthogonal to each other. The X axis is, for example, parallel to a horizontal plane and corresponds to a left-right direction. One side of the X axis is described as a −X side, and the other side of the X axis is described as a +X side. The Y axis is, for example, parallel to a horizontal plane and corresponds to a depth direction. One side of the Y axis is described as a −Y side, and the other side of the Y axis is described as a +Y side.

The light emitting device 12 emits the light LC, which is color light for projecting an image, to the +Z side along the optical axis AX parallel to the Z axis. The light emitting device 12 includes a light emitting element 20 and a heat sink 21.

The light emitting element 20 has two end surfaces 20a and 20b and emits the light LC. The end surface 20a of the two end surfaces is disposed on the +Z side, may have unevenness with respect to an XY plane including the X axis and the Y axis, may be a flat surface parallel to the XY plane, and has unevenness with respect to the XY plane, for example. When viewed along the Z axis, the end surfaces 20a and 20b of the light emitting element 20 and a light emitting region R22 on the end surface 20a have a rectangular shape. The end surface 20b is a flat surface disposed on the −Z side of the end surface 20a and parallel to the XY plane. A detailed configuration of the light emitting element 20 will be described later.

The light LC is emitted from the end surface 20a of the light emitting element 20 toward the +Z side along the optical axis AX. If the projector 10 is a device capable of displaying a full-color image, the light LC is, for example, white light including red light, green light, and blue light. If the projector 10 is a device capable of displaying a monochromatic image, the light LC is light of the same color as the monochromatic image, for example, any color light of red light, green light, and blue light.

The heat sink 21 is disposed on the end surface 20b of the light emitting element 20 and releases heat generated by the light emitting element 20.

The diffusion plate 19 is disposed on an optical path of the light LC emitted from the light emitting device 12. The diffusion plate 19 diffuses the incident light LC on the XY plane and uniformizes illuminance of the light LC on the XY plane. The diffusion plate 19 may be omitted.

The light modulation device 13 is disposed on the optical path of the light LC emitted from the light emitting device 12 and passing through the diffusion plate 19. The light modulation device 13 is driven by receiving an electric signal input from an external input device or image forming device (not illustrated) via a control device (not illustrated), modulates the incident light LC according to image information included in the electric signal, and generates image light LM including a projection image.

The light modulation device 13 includes a light-incident-side polarizer 16, a liquid crystal element 17, and a light-exiting-side polarizer 18.

The light-incident-side polarizer 16 is disposed on the optical path of the light LC emitted from the light emitting device 12 and passing through the diffusion plate 19. For example, the light-incident-side polarizer 16 is in contact with the liquid crystal element 17 from the −Z side, and may be disposed at an appropriate interval from the liquid crystal element 17 in the Z axis. The light-incident-side polarizer 16 has a polarization plane parallel to the XY plane, and emits predetermined polarized light of the incident light LC to the +Z side along the Z axis. The predetermined polarized light is, for example, P-polarized light.

The liquid crystal element 17 is disposed on the optical path of the predetermined polarized light LC emitted from the light-incident-side polarizer 16. A modulation plane including an image forming region R26 of the liquid crystal element 17 is parallel to the XY plane. When viewed along the Z axis, the image forming region R26 of the liquid crystal element 17 presents a rectangular shape, and is substantially similar to the light emitting region R22 of the light emitting element 20 in shape. Area of the image forming region R26 of the liquid crystal element 17 is the same as or slightly smaller than area of the light emitting region R22 of the light emitting element 20.

The liquid crystal element 17 is, for example, a transmissive liquid crystal panel. In the liquid crystal panel constituting the liquid crystal element 17, a plurality of pixels (not illustrated) are formed in a region corresponding to the image forming region R26 of the liquid crystal element 17. The plurality of pixels are arranged along the X axis and the Y axis. The pixels each include a switching element. The switching element is, for example, a polysilicon thin film transistor (TFT). The liquid crystal element 17 emits the image light LM generated by the liquid crystal panel to the +Z side along the Z axis.

An electric signal corresponding to brightness of the color light at a relative position of each pixel in the image projected by the projector 10 is supplied from an external input device or image forming device to the switching element of the pixel of the liquid crystal panel. Each pixel of the liquid crystal panel modulates a vibration direction of the light LC, which is emitted from the light-incident-side polarizer 16, by the operation of the switching element according to the electric signal described above, and generates the image light LM having an illuminance distribution of color light according to the electric signal described above.

The light-exiting-side polarizer 18 is disposed on the optical path of the image light LM emitted from the liquid crystal element 17. For example, the light-exiting-side polarizer 18 is in contact with the liquid crystal element 17 from the +Z side, and may be disposed at an appropriate interval from the liquid crystal element 17 in the Z axis. The light-exiting-side polarizer 18 has a polarization plane parallel to the XY plane, and emits predetermined polarized light of the incident image light LM to the +Z side along the Z axis. The predetermined polarized light is, for example, P-polarized light.

The light-incident-side polarizer 16 and the light-exiting-side polarizer 18 are, for example, reflection type polarizing plates or absorption type polarizing plates. When it is desired to restrict generation of stray light inside the projector 10 and return light to the light emitting device 12, it is desirable to use an absorption type polarizing plate as the light-incident-side polarizer 16. When it is desired to restrict generation of stray light inside the projector 10 or return light to the liquid crystal element 17, it is desirable to use an absorption type polarizing plate as the light-exiting-side polarizer 18.

The projection optical system 14 is disposed on the optical path of the image light LM emitted from the light modulation device 13. The projection optical system 14 projects the incident image light LM on the screen SCR disposed on the +Z side, and enlarges and displays an image, which is transmitted and output from the image forming device to the liquid crystal element 17 of the light modulation device 13, on the screen SCR.

### Light Emitting Element

Next, the light emitting element 20 according to an embodiment of the present disclosure will be described. FIG. 2 is a plan view of the light emitting element 20 and corresponds to a view of the light emitting element 20 viewed from the +Z side along the Z axis.

As illustrated in FIG. 2, the end surface 20a of the light emitting element 20 is divided into the light emitting region R22 including a center and a peripheral region R24 on an outer peripheral side of the light emitting region R22 when viewed along the Z axis. A plurality of nanocolumns 57 are formed in substantially the entire light emitting region R22 at intervals along the X axis and the Y axis. Some of the plurality of nanocolumns 57 are illustrated in FIG. 2, and the remaining nanocolumns 57 are omitted.

As illustrated in FIG. 2, an interval Px between centers of two nanocolumns 57 adjacent to each other in the X axis and an interval Py between centers of two nanocolumns 57 adjacent to each other in the Y axis are, for example, 1 nm or more and 500 nm or less. For example, the intervals Px and Py are equal to each other, and the plurality of nanocolumns 57 are periodically arranged at intervals along each of the X axis and the Y axis. The plurality of nanocolumns 57 may be arranged in, for example, a rectangular lattice shape, a triangular lattice shape, a honeycomb lattice shape, a cugome lattice shape, or a maple leaf lattice shape on a surface parallel to the XY plane, in addition to being arranged in a square lattice shape when viewed from the +Z side along the Z axis as illustrated in FIG. 2.

A distance Dx between the nanocolumns 57 and 57 located at both ends of the plurality of nanocolumns 57 arranged along the X axis and a distance Dy between the nanocolumns 57 and 57 located at both ends of the plurality of nanocolumns 57 arranged along the Y axis are appropriately set according to a size of the light emitting region R22 along the X axis and a size of the light emitting region R22 along the Y axis.

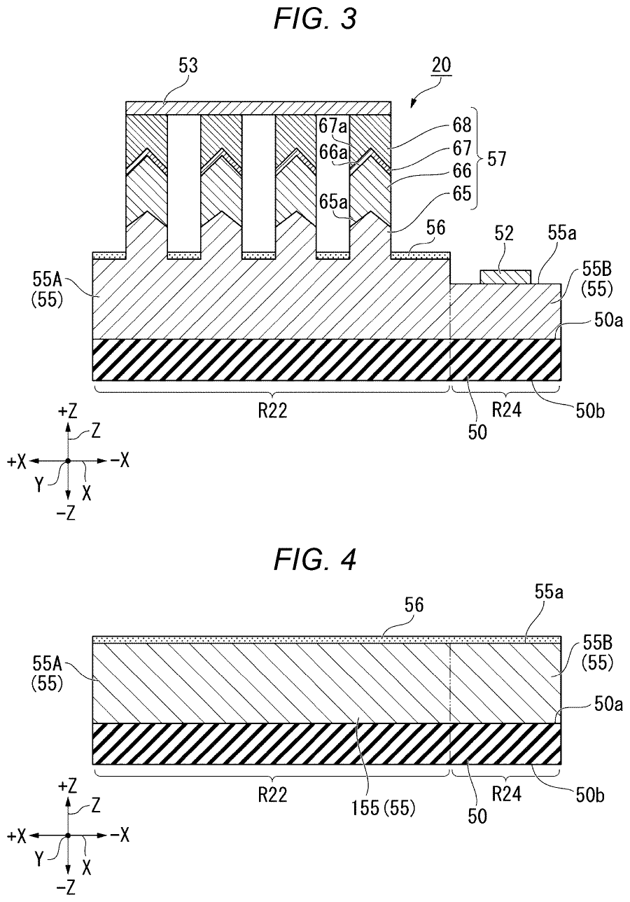

FIG. 3 is a cross-sectional view of the light emitting element 20 taken along a line III-III in FIG. 2. As illustrated in FIG. 3, the light emitting element 20 includes a substrate 50, a semiconductor layer 55, a mask layer 56, a plurality of the nanocolumns 57, and conductive layers 52 and 53.

The substrate 50 constitutes a base of the light emitting element 20 and has a front surface 50a and a back surface 50b parallel to the XY plane. The substrate 50 is, for example, a silicon (Si) substrate, a GaN substrate, or a sapphire substrate.

In the embodiment, a sapphire substrate having a C-plane of plane orientation is used as the substrate 50. Since the substrate 50 is the sapphire substrate, when the semiconductor material of the semiconductor layer 55 formed at the front surface 50a on the +Z side of the substrate 50 is GaN, crystal quality of the semiconductor layer 55 made of GaN is high, and uniform crystal is formed at the front surface 50a. As a result, a current uniformly flows through a semiconductor layer 67 of the nanocolumn 57, and light emission efficiency of the light emitting element 20 is improved.

The semiconductor layer 55 is formed at the front surface 50a on the +Z side of the substrate 50. The semiconductor layer 55 is formed of, for example, an n-type GaN layer doped with Si.

A bottom surface of the semiconductor layer 55 on the −Z side is in contact with the front surface 50a of the substrate 50. In the semiconductor layer 55, as will be described later, a semiconductor layer 55A of the light emitting region R22 in which the plurality of nanocolumns 57 are formed in the XY plane on the +Z side protrudes further to the +Z side than a semiconductor layer 55B of the peripheral region R24. The front surface 50a of the semiconductor layer 55A is located on the +Z side of the back surface 50b of the semiconductor layer 55B.

The mask layer 56 is formed at a front surface of the semiconductor layer 55A on the +Z side. The mask layer 56 is formed of, for example, a layer containing titanium (Ti). A dimension of the mask layer 56 in the Z axis, that is, a thickness of the mask layer 56 is, for example, about 5 nm. A plurality of through holes are formed in the mask layer 56 in accordance with positions where the plurality of nanocolumns 57 are formed. The plurality of through holes act as openings, and the nanocolumns 57 grow from the through holes to the +Z side as described later. The mask layer 56 is a mask layer for forming the nanocolumns 57 in a plurality of selective small regions exposed to the +Z side by the plurality of through holes in a front surface 55a of the semiconductor layer 55A.

The plurality of nanocolumns 57 are formed in the plurality of small regions of the front surface 55a of the semiconductor layer 55A that are exposed without being covered with the mask layer 56. Each nanocolumn 57 is a columnar crystal structure extending from the semiconductor layer 55A to the +Z side along the Z axis, and is a nanostructure. Light emitted from the semiconductor layer 67 as a light emitting layer is emitted not only to the +Z side along the Z axis but also to a direction parallel to the XY plane and the −Z side. Therefore, a mirror may be provided on a side surface side or a back surface side of the nanocolumn 57, and a reflection structure for increasing the light emitted to the +Z side may be provided.

A shape of the nanocolumn 57 when viewed along the Z axis, that is, a shape of the nanocolumn 57 in plan view is, for example, a polygon or a circle. When the semiconductor material of the nanocolumn 57 contains GaN, the shape of the nanocolumn 57 in plan view is a hexagon. A maximum width of the nanocolumn 57 when viewed along the Z axis, that is, a diameter of the nanocolumn 57 is on the order of nm, and is, for example, 100 nm or more and 300 nm or less. When the shape of the nanocolumn 57 in plan view is a polygon, the diameter of the nanocolumn 57 means the diameter of the smallest circle containing the polygon therein. When the shape of the nanocolumn 57 in plan view is an ellipse, the diameter of the nanocolumn 57 means the diameter of the smallest circle containing the ellipse therein.

When the shape of the nanocolumn 57 in plan view is a circle, the center of the nanocolumn 57 means the center of the circle. When the shape of the nanocolumn 57 in plan view is a polygon, the center of the nanocolumn 57 means the center of the smallest circle containing the polygon therein. When the shape of the nanocolumn 57 in plan view is an ellipse, the center of the nanocolumn 57 means the center of the smallest circle containing the ellipse therein.

The nanocolumn 57 includes semiconductor layers 65, 66, 67, and 68. The semiconductor layers 65, 66, 67, and 68 are sequentially stacked from the −Z side to the +Z side along the Z axis. The semiconductor layers 66, 67, and 68 are formed by epitaxial growth as described later.

The semiconductor layer 65 is disposed on the most −Z side of the nanocolumn 57, is formed in the small region of the semiconductor layer 55 that is not covered with the mask layer 56 on the front surface 55a of the semiconductor layer 55A in the light emitting region R22, and extends from the semiconductor layer 55A to the +Z side along the Z axis. The semiconductor layer 65 corresponds to a first semiconductor layer described later and a first semiconductor layer disclosed in the claims. The semiconductor layer 65 is made of the same semiconductor material as the semiconductor layer 55, and is formed of, for example, an n-type GaN layer doped with Si.

A front surface 65a of the semiconductor layer 65 on the +Z side is inclined with respect to the XY plane, and extends to the +Z side as approaching a center thereof from an outer periphery thereof as viewed along the Z axis. The front surface 65a of the semiconductor layer 65 on the +Z side is formed by epitaxially growing n-type GaN in the formation of the semiconductor layer 65, and is narrowed on the +Z side toward the center as viewed along the Z axis. The front surface 65a of the semiconductor layer 65 corresponds to a first surface described later and a first surface disclosed in the claims.

The semiconductor layer 66 is disposed on the semiconductor layer 65 on the +Z side and is stacked on the semiconductor layer 65 on the +Z side. The semiconductor layer 66 corresponds to a buffer layer described later and a buffer layer disclosed in the claims.

A bottom surface of the semiconductor layer 66 on the −Z side is in contact with the front surface 65a of the semiconductor layer 65 from the +Z side, is inclined at the same angle as the front surface 65a of the semiconductor layer 65 with respect to the XY plane, and extends to the +Z side as approaching a center thereof from an outer periphery thereof as viewed along the Z axis.

A front surface 66a of the semiconductor layer 66 on the +Z side is inclined at an angle larger than the bottom surface of the semiconductor layer 66 on the −Z side with respect to the XY plane, and extends to the +Z side as approaching a center thereof from an outer periphery thereof as viewed along the Z axis. A distance in the z axis between an outer peripheral end and the center of the front surface 66a of the semiconductor layer 66 is larger than a distance in the Z axis between an outer peripheral end and the center of the bottom surface of the semiconductor layer 66 on the −Z side. A dimension of the semiconductor layer 66 in the Z axis, that is, a thickness of the semiconductor layer 66 increases from the outer periphery toward the center.

The semiconductor layer 66 is implemented by a layer formed of a superlattice (SL) of InGaN and GaN. The layer formed of the superlattice of InGaN and GaN is formed of a stacked body in which an InGaN layer and a GaN layer are alternately stacked along the Z axis. A Z-axis dimension of the InGaN layer in the superlattice of InGaN and GaN, that is, a thickness of the InGaN layer is, for example, about 5 nm. A Z-axis dimension of the GaN layer in the superlattice of InGaN and GaN, that is, a thickness of the GaN layer is about the same as the thickness of the InGaN layer, and is, for example, about 5 nm.

The front surface 66a of the semiconductor layer 66 on the +Z side corresponds to a third surface described later and a third surface disclosed in the claims, is a facet plane, and is, for example, a (10-11) surface of the layer formed of the superlattice of InGaN and GaN.

A dimension of the outer peripheral end of the semiconductor layer 66 in the Z axis, that is, a thickness of the outer peripheral end of the semiconductor layer 66 is, for example, 100 nm or more and 400 nm or less. An average composition ratio of In in the semiconductor layer 66 is adjusted according to the thickness of the semiconductor layer 66. The semiconductor layer 66 acts as pseudo mixed crystal of InGaN in which the average composition ratio of In is adjusted according to the thickness. In the light emitting element 20 of the embodiment, the average composition ratio of In in the semiconductor layer 66 is at least higher than 18%, preferably 20% or more, and more preferably 25% or more and less than 30%.

When the average composition ratio of In in the semiconductor layer 66 is about 22%, the angle formed by the front surface 66a of the semiconductor layer 66 with respect to the XY plane is about 60°, and the angle formed by the front surface of the semiconductor layer 66 on the −Z side and the front surface 65a of the semiconductor layer 65 with respect to the XY plane is about 30°.

The semiconductor layer 67 is disposed at the semiconductor layer 66 on the +Z side and is stacked on the semiconductor layer 66 on the +Z side. The semiconductor layer 67 corresponds to an active layer, and corresponds to a light emitting layer described later and a light emitting layer disclosed in the claims.

A bottom surface of the semiconductor layer 67 on the −Z side is in contact with the front surface 66a of the semiconductor layer 66 from the +Z side, is inclined at the same angle as the front surface 66a of the semiconductor layer 66 with respect to the XY plane, and extends to the +Z side as approaching a center thereof from an outer periphery thereof as viewed along the Z axis. A front surface 67a of the semiconductor layer 67 on the +Z side is inclined at the same angle as the front surface 66a of the semiconductor layer 66 and the bottom surface of the semiconductor layer 67 on the −Z side with respect to the XY plane, and extends to the +Z side as approaching a center thereof from an outer periphery thereof as viewed along the Z axis. A dimension of the semiconductor layer 67 in the Z axis, that is, a thickness of the semiconductor layer 67 is substantially uniform in the XY plane from the outer periphery to the center.

The front surface 67a of the semiconductor layer 67 corresponds to a second surface described later and a second surface disclosed in the claims, is a facet plane, and is, for example, a (10-11) surface of a layer having a multi-quantum well (MQW) structure of InGaN and GaN.

The semiconductor layer 67 has a stacked structure of an InGaN layer and a GaN layer, and has an MQW. The stacked structure of the InGaN layer and the GaN layer is a stacked body in which the InGaN layer and the GaN layer are alternately stacked along the Z axis.

The dimension of the semiconductor layer 67 in the Z axis, that is, the thickness of the semiconductor layer 67 is, for example, 20 nm or more and 200 nm or less. Similarly to the semiconductor layer 66, an average composition ratio of In in the semiconductor layer 67 is adjusted according to the thickness of the semiconductor layer 67. In the light emitting element 20 of the embodiment, the composition ratio of In in the InGaN layer having the highest In composition in the semiconductor layer 67 is at least higher than the average composition ratio of In in the semiconductor layer 66 and is 30% or more, for example, 33% or more and 35% or less. The average composition ratio of In in the semiconductor layer 67 is desirably 30% or more.

For example, when the average composition ratio of In in the semiconductor layer 66 is about 22% and the average composition ratio of In in the semiconductor layer 67 is about 33%, the angle formed by the front surface 67a of the semiconductor layer 67 with respect to the XY plane is about 60°.

A band gap of InGaN contained in the semiconductor layers 66 and 67 is relatively narrow compared to that in other semiconductor materials. In the light emitting element 20 of the embodiment, the semiconductor layer 66 in which the average composition ratio of In is lower than that of the semiconductor layer 67 is disposed as a buffer layer on the −Z side of the semiconductor layer 67 as an active layer, that is, below the semiconductor layer 67. By disposing the semiconductor layer 66 between the semiconductor layer 65 and the semiconductor layer 67, a difference in lattice constant between the semiconductor layer 65 containing n-type GaN and the semiconductor layer 67 containing InGaN is relaxed.

Since the average composition ratio of In in the semiconductor layer 66 is higher than that in a semiconductor layer of a light emitting element in the related art, the semiconductor layer 66 having the front surface 66a and formed of a superlattice of InGaN and GaN is disposed at a portion on the +Z side of a center of the nanocolumn 57 in a direction along the Z axis, that is, at an upper portion of the nanocolumn 57, as a hexagonal pyramidal structure having a (10-11) facet plane.

Although the average composition ratio of In in the semiconductor layer 66 in the light emitting element 20 of the embodiment is at least lower than 18%, it has been confirmed that the (10-11) surface appears well on the front surface 66a even when the average composition ratio of In in the semiconductor layer 66 is about 16% as described later. When the average composition ratio of In in the semiconductor layer 66 is excessively low, for example, less than 15%, a (10-12) surface, a (10-13) surface, or the like may coexist in addition to the (10-11) surface on the front surface 66a of the semiconductor layer 66. In this case, the crystal quality and characteristics of the semiconductor layer 67 growing from the front surface 66a of the semiconductor layer 66 to the +Z side become non-uniform in a plane parallel to the XY plane, threading dislocations and defects occur in the semiconductor layer 67, and the light emission efficiency of the light emitting element 20 may decrease.

When the average composition ratio of In in the semiconductor layer 66 is 20% or more, In smoothly enters the semiconductor layer 67 when the semiconductor layer 67 having a higher average composition ratio of In is grown from the front surface 66a of the semiconductor layer 66. By disposing the semiconductor layer 66, even when a temperature of an environment in which the light emitting element 20 is manufactured is relatively high, the desired semiconductor layer 67 in which the average composition ratio of In is high and is 30% or more is obtained, and the light emission efficiency of the light emitting element 20 is improved.

When a current is injected into the light emitting element 20, carriers are satisfactorily recombined, and luminance of the light LC emitted from the light emitting element 20 is improved. In the semiconductor layer 67, since the composition ratio of In in the InGaN layer having the highest In composition is 30% or more, and for example, the average composition ratio of In is 30% or more and relatively high, the wavelength band of the light LC can be easily a longer red wavelength band among visible wavelength bands.

The semiconductor layer 68 is disposed on the semiconductor layer 67 on the +Z side and is stacked on the semiconductor layer 67 on the +Z side. The semiconductor layer 68 corresponds to a second semiconductor layer described later and a second semiconductor layer disclosed in the claims. The semiconductor layer 68 is made of a semiconductor material having conductivity different from that of the semiconductor layer 55, and is formed of, for example, a p-type GaN layer doped with magnesium (Mg).

A bottom surface of the semiconductor layer 68 on the −Z side is inclined at the same angle as the front surface 67a of the semiconductor layer 67 with respect to the XY plane, and extends to the +Z side as approaching a center thereof from an outer periphery thereof as viewed along the Z axis.

An insulating layer (not illustrated) may be formed at a front surface of the mask layer 56 on the +Z side. A front surface of the insulating layer (not illustrated) on the +side is at the same position as a front surface of the semiconductor layer 68 of the plurality of nanocolumns 57 on the +Z side in the Z axis, and constitutes substantially the same surface as the front surface of the semiconductor layer 68 on the +Z side. A refractive index of the insulating layer (not illustrated) is lower than an effective refractive index of the semiconductor layer 67 of the nanocolumn 57. The insulating layer (not illustrated) is formed of, for example, a silicon oxide (SiO₂) layer or an aluminum oxide (Al₂O₃) layer.

The conductive layer 52 is disposed on a side of the plurality of nanocolumns 57 in the XY plane, and is formed at the front surface 55a of the semiconductor layer 55B in the peripheral region R24 of the semiconductor layer 55. The conductive layer 52 is electrically coupled to the semiconductor layer 67 of the nanocolumn 57 via the semiconductor layer 55 and the semiconductor layer 65 and 66 of the nanocolumn 57. The conductive layer 52 corresponds to a first electrode of the light emitting element 20, and is one electrode for injecting a current into the semiconductor layer 67 of the nanocolumn 57.

The conductive layer 52 is formed of a layer made of a conductive material, and may be formed of, for example, an aluminum (Al) layer or a gold (Au) layer, or may be formed of a layer formed of a stacked body in which a Ti layer, an Al layer, and an Au layer are stacked in this order on the +Z side.

The conductive layer 53 is disposed on the +Z side, that is, on an upper side of the plurality of nanocolumns 57, and is formed over front surfaces of the plurality of semiconductor layers 68 on the +Z side. The conductive layer 53 is electrically coupled to the semiconductor layer 67 via the semiconductor layer 68 of the nanocolumn 57. The conductive layer 53 corresponds to a second electrode of the light emitting element 20, and is the other electrode for injecting a current into the semiconductor layer 67 of the nanocolumn 57.

The conductive layer 53 is formed of a layer made of a conductive material, for example, Indium Tin Oxide (ITO), and may be formed of an Al layer or an Au layer.

In the light emitting element 20, the p-type semiconductor layer 68 of the nanocolumn 57, the semiconductor layer 67 not doped with impurities, and the n-type semiconductor layer 65 constitute a pin diode. A band gap in the semiconductor layers 65 and 68 is larger than the band gap in the semiconductor layer 67. When a forward bias voltage corresponding to the pin diode is applied between the conductive layers 52 and 53 and a current is injected, recombination of electrons and holes occurs in the semiconductor layer 67, and light is generated.

### Method for Manufacturing Light Emitting Element

Next, a method for manufacturing the light emitting element 20 according to an embodiment of the present disclosure will be described. FIGS. 4 to 6 are cross-sectional views illustrating the method for manufacturing the light emitting element 20, and correspond to views taken along a line III-III in FIG. 2.

First, a process of forming the semiconductor layer 55 on the front surface 50a of the substrate 50 is performed by stacking a substrate 155 made of n-type GaN crystal or the like on the +Z side of the front surface 50a of the substrate 50 such as a sapphire substrate. Alternatively, the semiconductor layer 55 may be formed by epitaxially growing an n-type GaN layer on the front surface 50a of the substrate 50 by a metal organic chemical vapor deposition method or the like.

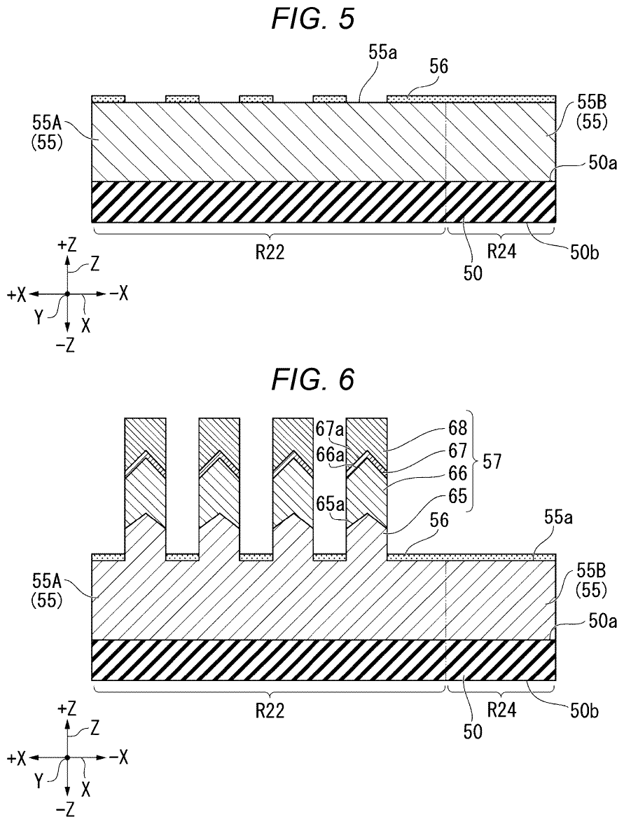

Subsequently, as illustrated in FIG. 4, the mask layer 56 formed of a Ti layer or the like having a thickness of about 5 nm is formed at the front surface 55a of the semiconductor layer 55. Thereafter, as illustrated in FIG. 5, a process of patterning the mask layer 56 in accordance with the arrangement of the plurality of nanocolumns 57 on the XY plane to form a small region, in which the front surface 55a of the semiconductor layer 55 is exposed, is performed. For example, a deposition method or the like may be used to form the mask layer 56 on the entire surface 55a of the semiconductor layer 55. For patterning the mask layer 56, electron beam (EB) lithography, dry etching, or the like may be used. By patterning the mask layer 56, a plurality of openings corresponding to relative arrangement of the plurality of nanocolumns 57 are formed in the mask layer 56, and the front surface 55a of the small region in which the plurality of nanocolumns 57 are formed in the front surface 55a of the semiconductor layer 55 is exposed.

Next, as illustrated in FIG. 5, a process of forming the nanocolumn 57 in the small region of the semiconductor layer 55 not covered with the mask layer 56 from the +Z side is performed. In order to form the nanocolumn 57, a molecular beam epitaxy (MBE) method, a metal organic chemical vapor deposition (MOCVD) method, or the like may be used. By using appropriate growth conditions for each of the semiconductor layers 65, 66, 67, and 68, the mask layer 56 acts as a selective growth mask, and each of the columnar semiconductor layers 65, 66, 67, and 68 grows in the opening of the mask layer 56 and extends to the +Z side along the Z axis.

In the process of growing the nanocolumn 57 to the +Z side along the Z axis, in a growth stage of each of the columnar semiconductor layers 65, 66, 67, and 68, the amount of irradiation of the semiconductor material of each semiconductor layer is appropriately adjusted from the +Z side and an outer peripheral side in the XY plane with respect to the formation region of the columnar body, that is, from obliquely above. The appropriate growth conditions for each of the semiconductor layers 65, 66, 67, and 68 include an irradiation rate of the semiconductor material of each semiconductor layer.

Although not illustrated, after a plurality of nanocolumns 57 are formed, the conductive layer 53 is formed over the semiconductor layer 68 of the plurality of nanocolumns 57 in the light emitting region R22 corresponding to a display region by using electrode patterning or the like. The mask layer 56 in the peripheral region R24 is removed, a +Z side portion of the semiconductor layer 55 in the peripheral region R24 is removed using dry etching or the like, and the conductive layer 52 is formed at the front surface 55a of the semiconductor layer 55B by using electrode patterning or the like.

The light emitting element 20 illustrated in FIG. 3 can be manufactured by performing the above-described processes.

### Prototype Example

Next, a protype example of the light emitting element 20 of the present embodiment will be described. The element of the prototype example was manufactured based on the configuration and the manufacturing method of the light emitting element 20 described above.

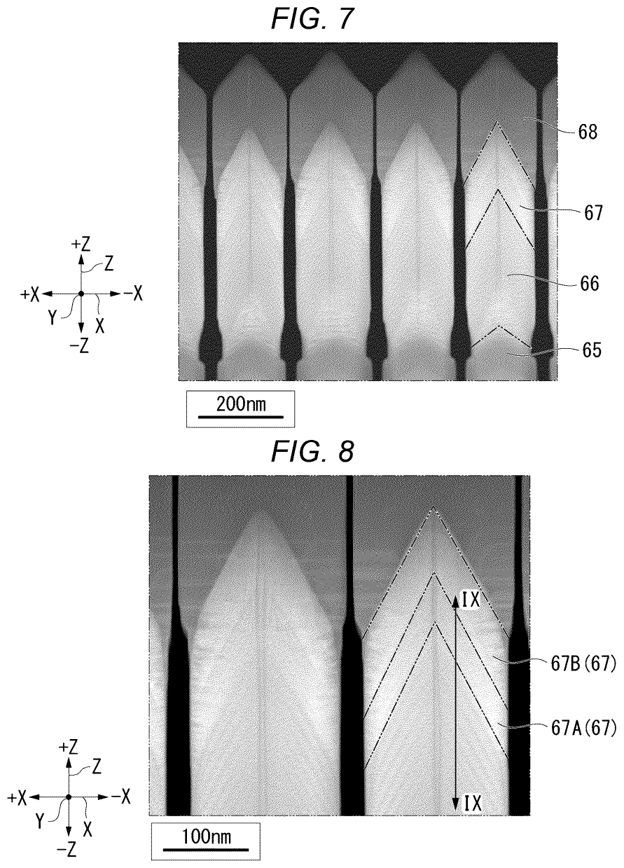

FIG. 7 is a high-angle annular dark field scanning transmission electron microscopy (HAADF-STEM) image of a plurality of nanocolumns 57 of the light emitting element 20 according to the first prototype example. FIG. 8 is an enlarged view of a part of the HAADF-STEM image of FIG. 7. In the first prototype example, an average composition ratio of In in the semiconductor layer 66 was assumed to be 25%, and an average composition ratio of In in the semiconductor layer 67 was assumed to be 33%. From FIGS. 7 and 8, it can be confirmed that the high-quality semiconductor layers 66 and 67 in which crystal defects are hardly observed are formed in the columnar nanocolumns 57.

As illustrated in FIG. 8, a semiconductor layer 67A that can act as a barrier layer formed of a superlattice of InGaN and GaN was formed in a portion of the semiconductor layer 67 on the −Z side. A semiconductor layer 67B acting as an MQW of InGaN and GaN was formed in a portion of the semiconductor layer 67 on the +Z side.

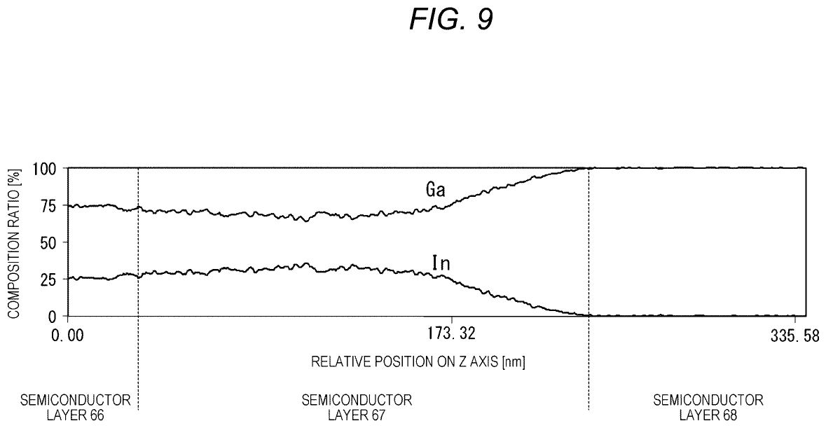

FIG. 9 is a graph showing average composition ratios of In and Ga in a range of a line IX-IX in FIG. 8. As illustrated in FIG. 9, the average composition ratio of In in the semiconductor layer 66 was about 25% as assumed, and the average composition ratio of In in the semiconductor layer 67 was about 33% as assumed.

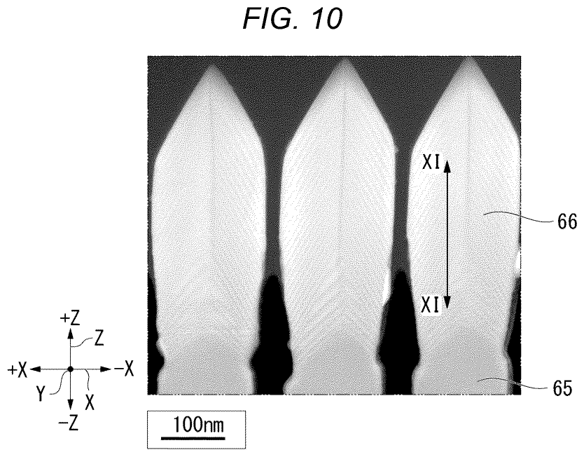

FIG. 10 is an HAADF-STEM image of the semiconductor layers 65 and 66 of a plurality of nanocolumns 57 of the light emitting element 20 according to a second prototype example. In the second prototype example, an average composition ratio of In in the semiconductor layer 66 was assumed to be 16%. From FIG. 10, it can be confirmed that the high-quality semiconductor layer 66 in which crystal defects are hardly observed is formed in the columnar nanocolumns 57.

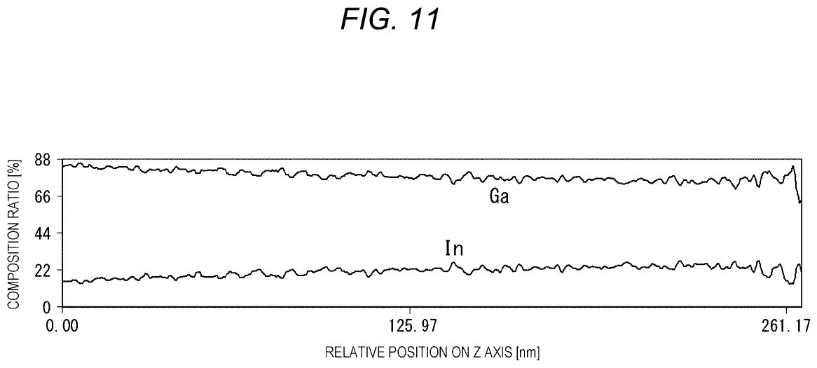

FIG. 11 is a graph showing average composition ratios of In and Ga in a range of a line XI-XI in FIG. 10. As illustrated in FIG. 11, the average composition ratio of In in the semiconductor layer 66 was about 16% as assumed.

The light emitting element 20 of the embodiment described above includes the semiconductor layer (first semiconductor layer) 65, the semiconductor layer (second semiconductor layer) 68, the semiconductor layer (light emitting layer) 67, and the semiconductor layer (buffer layer) 66. The semiconductor layer 65 has the front surface (first surface) 65a on the +Z side. The semiconductor layer 68 has conductivity different from that of the semiconductor layer 65. In the embodiment, the semiconductor layer 65 has n-type conductivity, whereas the semiconductor layer 68 has p-type conductivity. The semiconductor layer 67 is disposed between the semiconductor layers 65 and 68 in the Z axis. The semiconductor layer 66 is disposed between the semiconductor layers 65 and 68 in the Z axis. In the light emitting element 20 of the embodiment, the semiconductor layer 67 has a stacked body in which InGaN layers and GaN layers are alternately stacked in the Z axis, and has the front surface (second surface) 67a that is a facet plane. A composition ratio of In in the InGaN layer having the highest composition of In in the semiconductor layer 67 is 30% or more. The semiconductor layer 66 has the front surface (third surface) 66a that is a facet plane. The composition ratio of In in the semiconductor layer 66 is at least 18% or more, and preferably 20% or more.

In the light emitting element 20 of the embodiment, in the light emitting element including the nanocolumn 57, the nanocolumn 57 includes the semiconductor layer 66 containing InGaN and GaN as a buffer layer between the semiconductor layer 65 containing n-type GaN and the semiconductor layer 67 containing InGaN and GaN as a light emitting layer. The InGaN layer having the highest composition of In in the semiconductor layer 67 has a high composition ratio of In of 30% or more, whereas an average composition ratio (composition ratio) of In in the semiconductor layer 66 is lower than the composition ratio of In in the InGaN layer having the highest ratio of In in the semiconductor layer 67 and is 20% or more and less than 30%. In the light emitting element 20 of the embodiment, since a difference in lattice constant between the semiconductor layers 65 and 67 is relaxed by the semiconductor layer 66, the occurrence of crystal defects in the semiconductor layer 67 can be restricted, the high-quality semiconductor layer 67 can be formed, and the light LC in the red wavelength band on the long wavelength side in the visible wavelength band can be emitted from the semiconductor layer 67. That is, it is possible to achieve both sufficient thicknesses of the semiconductor layers 66 and 67 for light confinement in the nanocolumns 57 and restriction of occurrence of crystal defects in the semiconductor layer 67.

In the light emitting element 20 of the embodiment, the front surface 65a of the semiconductor layer 65 is a facet plane.

According to the light emitting element 20 of the embodiment, since a (10-11) surface as a facet plane is formed at the front surface 65a of the semiconductor layer 65, the (10-11) surface can be provided using the front surface 66a as a facet plane without excessively increasing the thickness of the semiconductor layer 66 grown on the +Z side of the front surface 65a. This can simplify the manufacturing process of the light emitting element 20 of the embodiment and reduce a size of the light emitting element 20.

In the light emitting element 20 of the embodiment, the semiconductor layer 66 is a superlattice layer that is a stacked body in which InGaN layers and GaN layers are alternately stacked in the Z axis.

According to the light emitting element 20 of the embodiment, since the semiconductor layer 66 is formed of a superlattice of InGaN and GaN, the difference in lattice constant between the semiconductor layers 65 and 67 is more smoothly relaxed, and illuminance distribution and the amount of light LC emitted from the light emitting element 20 can be stabilized.

The projector 10 according to the embodiment includes the light emitting device 12 including the light emitting element 20 according to the embodiment.

According to the projector 10 of the embodiment, since the high-quality light emitting element 20 is provided, characteristics of the image light LM based on the light LC emitted from the light emitting element 20 can be improved, and display quality of a projection image can be improved.

Examples of an electronic device including the light emitting element 20 according to the embodiment include a head mounted display (HMD) and a printer in addition to the projector.

A method for manufacturing a light emitting element according to the embodiment is a method for manufacturing the light emitting element 20, and includes a process of sequentially forming the semiconductor layers 65, 66, 67, and 68 on the front surface 50a of the substrate 50 via the semiconductor layer 55 along a direction parallel to the Z axis intersecting the front surface 50a. In the above process, the (10-11) surface (third surface), which is a facet plane, is developed on the front surface 66a of the semiconductor layer 66 on the +Z side, and the (10-11) surface (second surface), which is a facet plane, is developed on the front surface 67a of the semiconductor layer 67 on the +Z side.

According to the method for manufacturing the light emitting element of the embodiment, the high-quality light emitting element 20 can be manufactured.

Preferable embodiments the of present disclosure have been described above in detail. The present disclosure is, however, not limited to the specific embodiments, and various modifications and changes can be made within the scope of the gist of the present disclosure disclosed in the claims.

### Summary of Disclosure

A summary of the present disclosure is appended below.

(Appendix 1) A light emitting element including:
a first semiconductor layer having a first surface;
a second semiconductor layer having conductivity different from that of the first semiconductor layer;
a light emitting layer disposed between the first semiconductor layer and the second semiconductor layer; and
a buffer layer disposed between the light emitting layer and the first semiconductor layer, in which
the light emitting layer has a stacked body in which indium gallium nitride (InGaN) layers and gallium nitride (GaN) layers are alternately stacked, and has a second surface that is a facet plane,
a composition ratio of indium (In) in each of the InGaN layers having a highest composition of In in the light emitting layer is 30% or more,
the buffer layer has a third surface that is a facet plane, and
the composition ratio of In in the buffer layer is 20% or more.

In the configuration of Appendix 1, since a difference in lattice constant between the first semiconductor layer and the light emitting layer is relaxed by the buffer layer and the occurrence of crystal defects in the light emitting layer is restricted, a high-quality light emitting layer can be formed. With the configuration of Appendix 1, it is possible to achieve both sufficient thicknesses of the buffer layer and the light emitting layer for light confinement in a nanocolumn of the light emitting element and restriction of occurrence of crystal defects in the light emitting layer.

(Appendix 2) The light emitting element according to Appendix 1, in which
the first surface is a facet plane.

According to the configuration of Appendix 2, the third surface can be provided as a facet plane without excessively increasing the thickness of the buffer layer grown on the first surface.

(Appendix 3) The light emitting element according to Appendix 1 or 2, in which
the buffer layer is a superlattice layer that is a stacked body in which InGaN layers and GaN layers are alternately stacked.

According to the configuration of Appendix 3, a difference in lattice constant between the first semiconductor layer and the light emitting layer is more smoothly relaxed, and illuminance distribution and the amount of light emitted from the light emitting element can be stabilized.

(Appendix 4) An electronic device including:
the light emitting element according to any one of Appendices 1 to 3.

According to the configuration of Appendix 4, it is possible to improve characteristics of image light based on light emitted from the light emitting element and to improve the display quality of an image displayed by the image light.

(Appendix 5) A method for manufacturing the light emitting element according to any one of Appendices 1 to 3, the method including:
a process of sequentially forming the first semiconductor layer, the buffer layer, the light emitting layer, and the second semiconductor layer on a front surface of a substrate along a direction intersecting the front surface, in which
in the process, a second surface that is a facet plane of the light emitting layer is developed, and a third surface that is a facet plane of the buffer layer is developed.

With the configuration of Appendix 5, a high-quality light emitting element can be provided as described above.

What is claimed is:

1. A light emitting element, comprising:
a first semiconductor layer having a first surface;
a second semiconductor layer having conductivity different from that of the first semiconductor layer;
a light emitting layer disposed between the first semiconductor layer and the second semiconductor layer; and
a buffer layer disposed between the light emitting layer and the first semiconductor layer, wherein
the light emitting layer has a stacked body in which indium gallium nitride (InGaN) layers and gallium nitride (GaN) layers are alternately stacked, and has a second surface that is a facet plane,
a composition ratio of indium (In) in each of the InGaN layers having a highest composition of In in the light emitting layer is 30% or more,
the buffer layer has a third surface that is a facet plane, and
the composition ratio of In in the buffer layer is 20% or more.

2. The light emitting element according to claim 1, wherein
the first surface is a facet plane.

3. The light emitting element according to claim 1, wherein
the buffer layer is a superlattice layer that is a stacked body in which InGaN layers and GaN layers are alternately stacked.

4. An electronic device, comprising:
the light emitting element according to claim 1.

5. A method for manufacturing the light emitting element according to claim 1, the method comprising:
a process of sequentially forming the first semiconductor layer, the buffer layer, the light emitting layer, and the second semiconductor layer on a front surface of a substrate along a direction intersecting the front surface, wherein
in the process, a second surface that is a facet plane of the light emitting layer is developed, and a third surface that is a facet plane of the buffer layer is developed.
